(19) United States
(12) Patent Application Publication
(10) Pub. No.: US 2007/0279262 A1
(43) Pub. Date: Dec. 6, 2007

(54) AUTOMATED RIGHT-HOLDERS REGISTRATION SYSTEM, METHOD AND COMPUTER PROGRAM PRODUCT FOR FACILITATING E-COMMERCE INVOLVING DIGITAL ASSETS

(75) Inventors: Ali Aydar, San Francisco, CA (US); David Rowley, Benicia, CA (US); Jordan Mendelson, San Francisco, CA (US); Richard Fletcher, San Francisco, CA (US); Daniel Racanelli, San Francisco, CA (US); Jason Toffaletti, San Francisco, CA (US)

Correspondence Address: Zilka-Kotab, PC, P.O. BOX 721120, SAN JOSE, CA, 95172-1120, US

(73) Assignee: SNOCAP, INC.

(21) Appl. No.: 11/740,903

(22) Filed: Apr. 26, 2007

Related U.S. Application Data
(60) Provisional application No. 60/796,169, filed on Apr. 27, 2006.

(51) Int. Cl. H03M 7/34

(52) U.S. Cl. 341/51

(57) ABSTRACT

A computer-implemented system, method and computer program product are provided. In use a request is received via a network from one of a plurality of entities which each has an interest in at least one corresponding digital asset. Moreover, an eligibility of the entity is automatically verified. An interface for the entity is thus conditionally provided for facilitating transactions involving the at least one digital asset, based on the verification.

### RELATED APPLICATION(S)

The present application claims priority to a provisional application filed Apr. 27, 2006 under application Ser. No. 60/796,169, which is incorporated herein by reference in its entirety.

### BACKGROUND AND FIELD OF THE INVENTION

The present invention relates to digital rights management, and more particularly to transactions involving digital assets.

### SUMMARY

A computer-implemented system, method and computer program product are provided. In use, a request is received via a network from one of a plurality of entities which each has an interest in at least one corresponding digital asset. Moreover, an eligibility of the entity is automatically verified. An interface for the entity is thus conditionally provided for facilitating transactions involving the at least one digital asset based on the verification.

### BRIEF DESCRIPTION OF THE DRAWINGS

FIG. 1 illustrates a network architecture, in accordance with one embodiment.

FIG. 2 shows a representative hardware environment that may be associated with the server computers and/or client computers of FIG. 1, in accordance with one embodiment.

FIG. 3 shows a method for generating interfaces that facilitate transactions involving at least one digital asset in accordance with one embodiment.

FIG. 4 shows a flow chart for generating and customizing an interface that facilitates transactions involving at least one digital asset, in accordance with another embodiment.

FIG. 5 shows a graphical user interface (GUI) for customizing a rule set associated with an interface that facilitates transactions involving at least one digital asset, in accordance with yet another embodiment.

FIG. 6 shows a method for registering a digital rights holder, in accordance with one embodiment.

FIG. 7 shows a method for generating an interface that facilitates transactions involving at least one digital asset in accordance with a user selection, in accordance with another embodiment.

FIG. 8 shows a GUI for generating an interface that facilitates transactions involving at least one digital asset, in accordance with yet another embodiment.

FIG. 9 shows a GUI that displays digital assets which have been uploaded, in accordance with one embodiment.

FIG. 10 shows a GUI which displays that no digital assets have been uploaded, in accordance with one embodiment.

FIG. 11 shows a GUI for updating a price of a digital asset, in accordance with one embodiment.

FIG. 12 shows a GUI which displays that no digital assets have been uploaded, in accordance with another embodiment.

FIG. 13 shows a method for providing code that is capable of displaying an e-commerce interface on a web page in which it is inserted, in accordance with one embodiment.

FIG. 14 shows a GUI in which code capable of displaying an e-commerce interface has been inserted into a web page, in accordance with another embodiment.

FIG. 15 shows a GUI in which code capable of displaying an e-commerce interface has been inserted into a web page, in accordance with yet another embodiment.

FIG. 16 shows a method for verifying a buyer to purchase a digital asset, in accordance with one embodiment.

FIG. 17 shows a flow chart for purchasing a digital asset, in accordance with one embodiment.

FIGS. 18A-C show GUIs utilized in purchasing a digital asset, in accordance with one embodiment.

FIG. 19 shows a flow for help pages, in accordance with one embodiment.

FIG. 20 shows a GUI for purchasing and previewing available digital assets, in accordance with one embodiment.

FIG. 21 shows a method for providing a preview of available digital assets, in accordance with another embodiment.

FIG. 22 shows a system in which an entity is associated with a plurality of interfaces, in accordance with one embodiment.

FIG. 23 shows a method far displaying an interface in conjunction with a web page in which a third party has an interest, in accordance with one embodiment,

FIG. 24 shows GUIs including links which initiate a transaction associated with a digital asset in accordance with one embodiment,

FIG. 25 shows a method for aggregating accounting information from a plurality of interfaces, in accordance with one embodiment.

FIG. 26 shows a system for generating interfaces that facilitate transactions involving at least one digital asset, in accordance with one embodiment.

### DETAILED DESCRIPTION

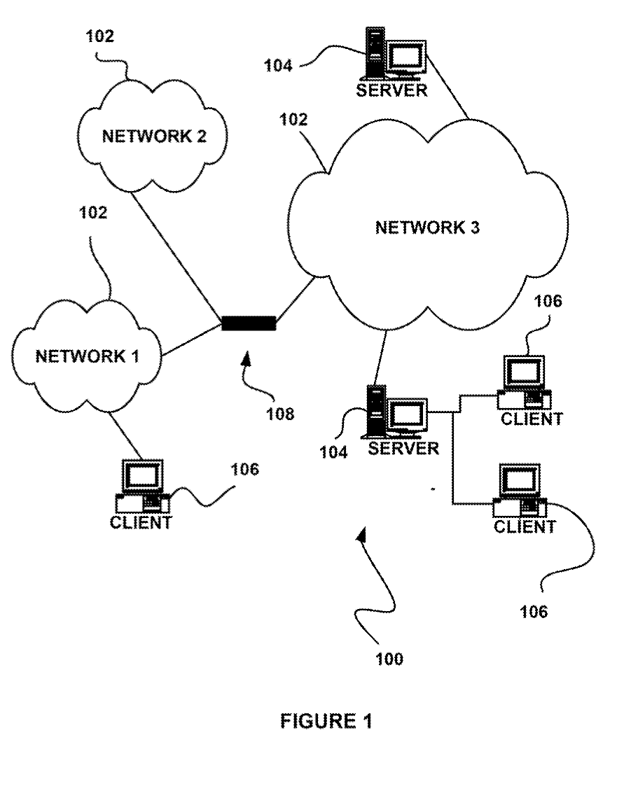

FIG. 1 illustrates a network architecture 100, in accordance with one embodiment. As shown, a plurality of networks 102 is provided. In the context of the present network architecture 100, the networks 102 may each take any form including, but not limited to a local area network (LAN), a wireless network, a wide area network (WAN) such as the Internet, peer-to-peer network, etc.

Coupled to the networks 102 are server computers 104 which are capable of communicating over the networks 102. Also coupled to the networks 102 and the server computers 104 is a plurality of client computers 106. Such server computers 104 and/or client computers 106 may, each include a desktop computer, lap-top computer, hand-held computer, mobile phone, personal digital assistant (PDA), peripheral (e.g. printer, etc.), any component of a computer, and/or any other type of logic, In order to facilitate communication among the networks 102, at least one gateway 108 is optionally coupled therebetween

As will be set forth later in greater detail, any one or more of the foregoing devices may be equipped with any of the digital asset management and/or related e-commerce functionality that will be the subject of discussion during reference to subsequent figures. Still yet, in some optional embodiments, for example, any of the foregoing devices may include any one or more of the features set forth in one or more of the following related applications: application Ser. No. 11/314,752 filed on Dec. 20, 2005, application Ser. No. 10/547,171 filed Dec. 20, 2005, application Ser. No. 11/314,753 filed Dec. 20, 2005, application Ser. No. 11/314,749 filed Dec. 20, 2005, application Ser. No. 11/314,167 filed Dec. 20, 2005, application Ser. No. 11/314,168 filed Dec. 20, 2005, application Ser. No. 11/314,732 filed Dec. 20, 2005, which are each incorporated herein by reference in their entirety for all purposes. Just way of example, the library database discussed therein may optionally be incorporated and used in a manner that will soon be set forth.

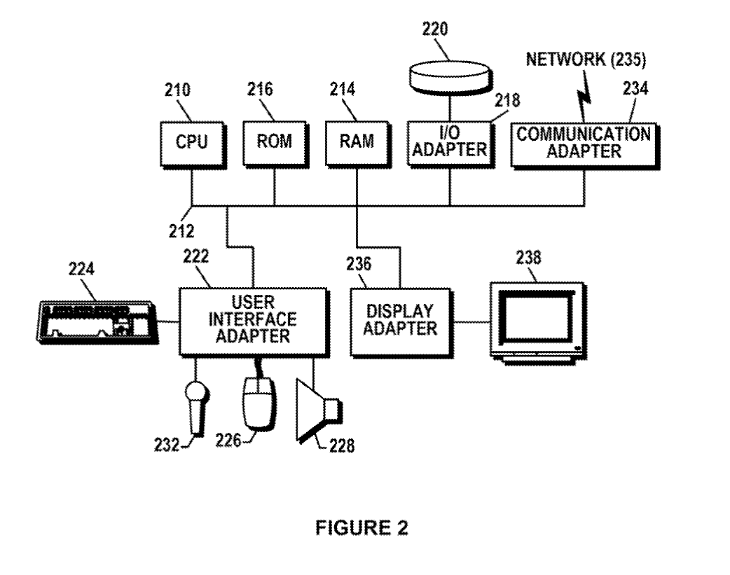

FIG. 2 shows a representative hardware environment that may be associated with the server computers 104 and/or client computers 106 of FIG. 1, in accordance with one embodiment. Such figure illustrates a typical hardware configuration of a workstation in accordance with one embodiment having a central processing unit 210, such as a microprocessor, and a number of other units interconnected via a system bus 212.

The workstation shown in FIG. 2 includes a Random Access Memory (RAM) 214, Read Only Memory (ROM) 216, an I/O adapter 218 for connecting peripheral devices such as disk storage units 220 to the bus 212, a user interface adapter 222 for connecting a keyboard 224, a mouse 226, a speaker 228, a microphone 232, and/or other user interface devices such as a touch screen (not shown) to the bus 212, communication adapter 234 for connecting the workstation to a communication network 235 (e.g., a data processing network) and a display adapter 236 for connecting the bus 212 to a display device 238,

The workstation may have resident thereon any desired operating system. It will be appreciated that an embodiment may also be implemented on platforms and operating systems other than those mentioned. One embodiment may be written using JAVA, C, and/or C++ language, or other programming languages, along with an object oriented programming methodology. Object oriented programming (OOP) has become increasingly used to develop complex applications.

Our course, the various embodiments set forth herein may be implemented utilizing hardware, software, or any desired combination thereof. For that matter, any type of logic may be utilized which is capable of implementing the various functionality set forth herein.

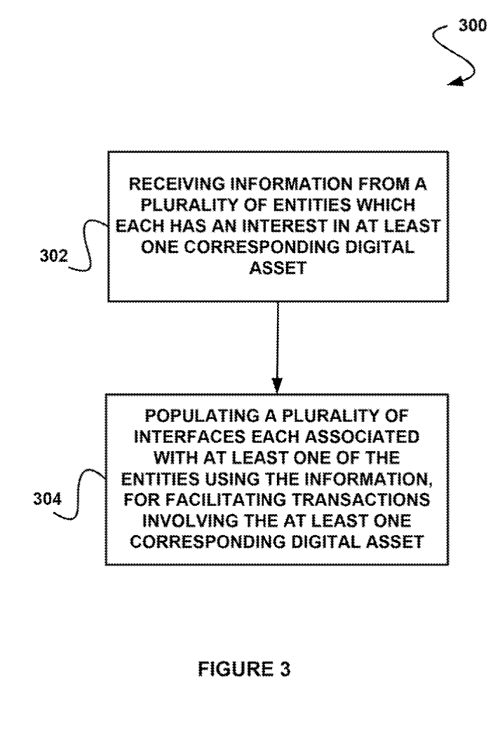

FIG. 3 shows a method 300 for generating interfaces that facilitate transactions involving at least one digital asset, in accordance with one embodiment. As an option, the method 300 may be implemented in the context of the architecture and environment of FIGS. 1 and/or 2. Of course however, the method 300 may be carried out in any desired environment.

As shown in operation 302, information is received from a plurality of entities which each has an interest in at least one corresponding digital asset. The entities may include any individual person, group of people (e.g. association, etc.), and/or business (e.g. corporation, etc.), etc. Of course, the entities may optionally have any type of interest in the digital asset.

For example, the aforementioned interest in the digital asset may, in one embodiment, include at least one right (e.g. copyright contractual right, legal right, etc.) with respect to the digital asset. In another embodiment, the aforementioned interest may refer to an exclusive or non-exclusive license under the above right in the digital asset. Still yet, the interest may simply refer to a capability of authorizing any activity with respect to the digital asset (e.g. as an agent, etc.). Thus, the interest may refer to any right either through original ownership, purchase, license, agency and/or any other capacity, to distribute, sell, and/or otherwise control/manage at least one aspect of the digital asset.

Furthermore, in the context of the present description, the digital asset may include video, audio, images, publications, lyrics, compositions, and/or any other content capable of being provided in a digital form. In one optional embodiment, the digital asset may include any asset in which an entity is capable of having an interest, as defined above.

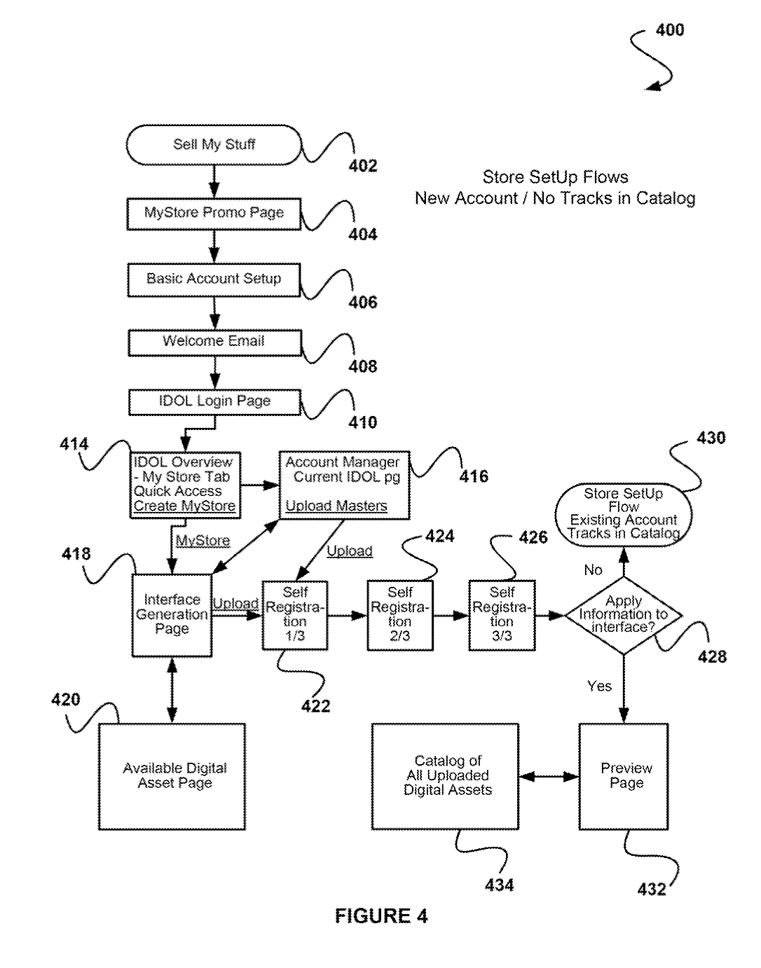

Still yet the information that is received from the plurality of entities may be received in any desired manner. Just by way of example, the information may be received utilizing a registration process performed by the plurality of entities. One exemplary registration process will be described in more detail with respect to FIG. 4.

In another exemplary embodiment, the information may be received by an entity uploading the information. Still yet, the information may be received utilizing a network (e.g. Internet, etc.). For instance, the information may be received at a server (e.g, see,, for example, the servers 104 of FIG. 1, etc.).

In the context of the present description, the information may refer to any information capable of being used directly or indirectly, at least in part, to populate at least one interface for facilitating transactions involving the aforementioned digital asset(s). For example, in one optional embodiment, the information may include or at least identify a digital asset in which the corresponding entity has an interest, a store name which will be utilized in providing the digital asset, a branding associated with the digital asset, a description of the digital asset, a price of the digital asset and/or any other information for that matter.

Utilizing such information, a plurality of interfaces, each associated with at least one of the entities may be populated for facilitating transactions involving the at least one digital asset. Note operation 304. The interfaces may include, for example, templates, store fronts, web pages, graphical user interfaces, and/or Flash interfaces. Of course, in the context of the present description, the interfaces may each include any interface capable of facilitating transactions involving the at least one digital asset. For example, the interfaces may facilitate a sale, purchase, and/or transfer of at least one interest associated with the digital asset. Of course, each of such interfaces may facilitate any type of transaction capable of being performed with respect to a digital asset.

In one specific embodiment, information associated with song tracks may be received from an entity (e.g. song artist etc.). In particular, the digital audio sound recordings themselves and/or information identifying the same (along with any information associated therewith) may be received. Such sound recordings and associated information may be populated within web interfaces, and the web interfaces may be embedded within web sites such that the entity (e.g. song artist, etc.) may sell the sound recordings,

More illustrative information will now be set forth regarding various optical architectures and features with which the foregoing technique may or may not be implemented, per the desires of the user. It should be strongly noted that the following information is set forth for illustrative purposes and should not be construed as limiting in any manner, Any of the following features may be optionally incorporated with or without the exclusion of other features described.

FIG. 4 shows a flow chart for generating and customizing an interface that facilitates transactions involving at least one digital asset, in accordance with another embodiment. As an option, the method 400 may be implemented in the context of the architecture and environment of FIGS. 1-3. Of course, however, the method 400 may be carried out in any desired environment. It should also be noted that the aforementioned definitions may apply during the present description.

As shown in operation 402, an entity selects to sell a digital asset. Of course, the entity may select to perform any transaction with respect to the digital asset. Such selection may be made by visiting a web site capable of allowing the entity to create an interface for selling the digital asset. As another option, the selection may be made by downloading an application that is capable of allowing the entity to create an interface for selling the digital asset. Of course, such selection may be made in any desired manner.

Based on the selection, the entity is provided with a promotion page, in operation 404. The promotion page may provide information to the entity, where such information is associated with an interface capable of being generated by the entity for selling the digital asset. From the promotion page, the entity may be provided with an account set-up page in operation 406.

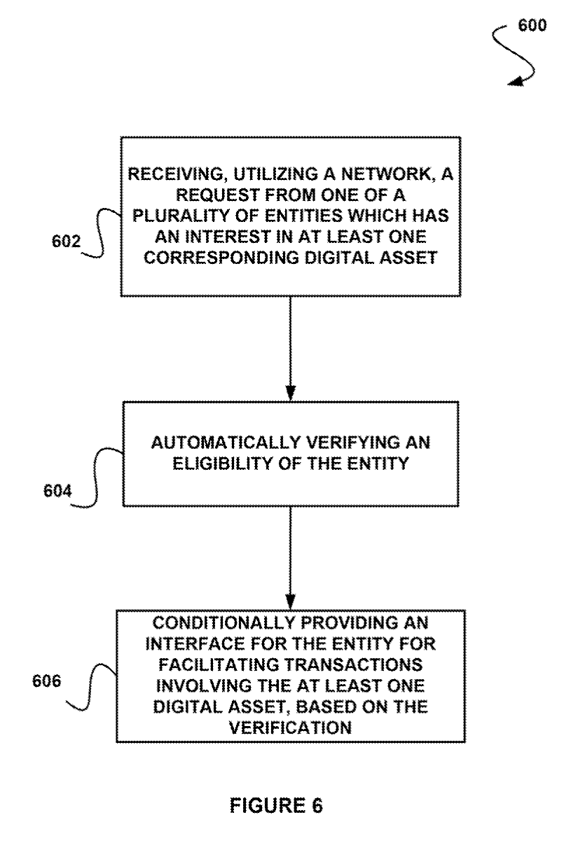

Just by way of example, the promotion page may contain a link to the account set-up page. The account set-up page may allow the entity to set up an account for selling the digital asset. For instance, the entity may provide any information associated with the entity and/or any interest it has that are associated with a digital asset. As an option, such account information may be stored in a database. Examples of such account set-up will be described with respect to FIG. 6.

As an option, the account information provided by the entity may include a category with which the entity is associated. Just by way of example, the entity may be allowed to select from four categories including a first category in which the entity is a major label (e.g., owns or controls at least the majority of digital sound recording assets), a second category in which the entity is an independent label (e.g., owns or controls many digital sound recording assets), a third category in which the entity is an individual (e.g. owns or controls its own created digital sound recording assets or those of another), and a fourth category in which the entity only owns or controls an interest in preventing transactions involving associated digital sound recording assets. If the entity is associated with the fourth category, the entity may be required to upsell to a third category entity account, For the first, second and third category entities, such entities may be allowed to create an account.

Once the entity has set up an account at page, a welcome e-mail may be sent to the entity, as shown in operation 408. The welcome e-mail may be sent to an e-mail address specified by the entity during the account set-up at page. The welcome e-mail may include any information associated with generating an interface for facilitating transactions with respect to any digital assets associated with the entity. The welcome e-mail may also include a link to a log-in page as indicated in operation 410.

The log-in page may allow the entity to log-in using a username and password in order to access an account for generating/managing an interface for facilitating transactions with respect to any digital assets associated with the entity. For instance, such username and password may be provided by the entity during the account set-up. After the entity has provided the log-in information at page, an overview page is displayed. The overview page may contain links to an upload page as indicated in operation 416 and to an interface generation page as indicated in operation 418. As shown, the upload page and interface generation page may both contain links to one another.

Specifically, the upload page may provide a link to a self registration page where the entity may upload any digital assets with which it is associated. In addition to uploading digital assets, the entity may also upload information associated with digital assets (e.g. descriptions, lyrics (the rights to which it owns, controls, or to which it has licensed), histories, etc.). Further, the upload page may provide a catalog of all digital assets that have already been uploaded.

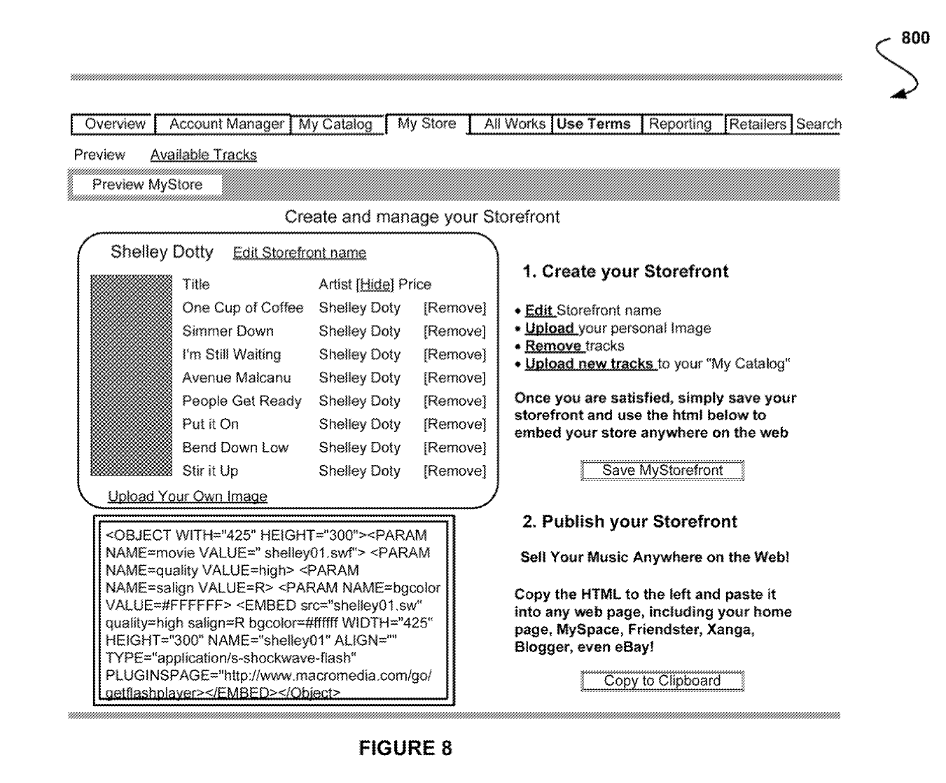

In addition, the interface generation page may provide a preview of a current interface for facilitating transactions with respect to any digital assets associated with the entity. In one example the interface may be an empty interface template prior to the entity customizing the interface. One example of such interface generation page will be described in further detail with respect to FIG. 8.

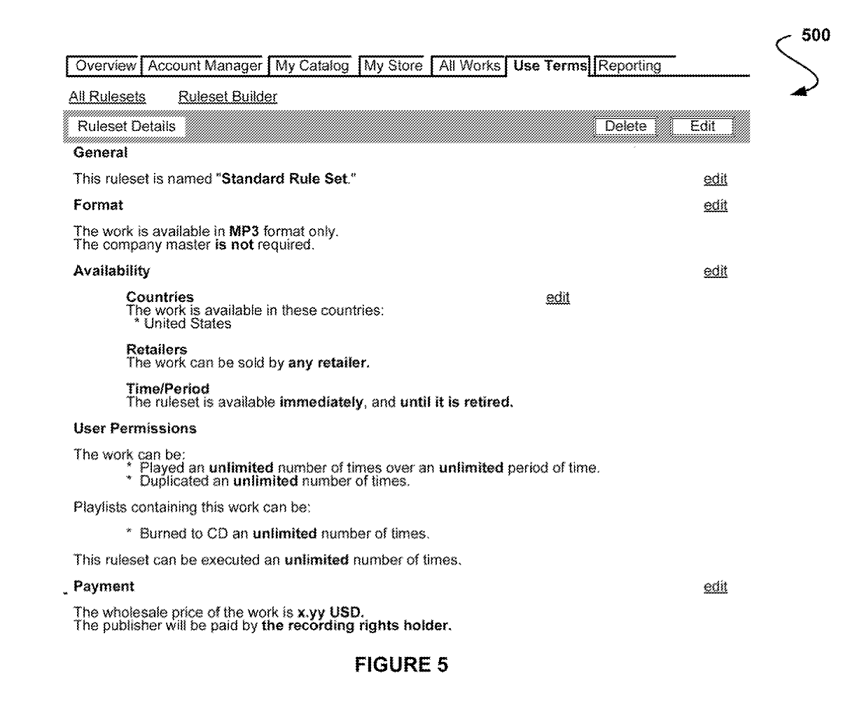

From the interface generation page, a link may be provided to an available digital asset page in operation 420. The available digital asset page may provide a catalog of all digital assets that have been uploaded. As another option, the available digital asset page may provide a list of digital assets that have been uploaded and that have appropriate rule sets applied, as will be described in further detail with respect to FIG. 5. Still yet, the available digital asset page may include a link to the upload page.

From the interface generation page and the upload page, the entity, may select to upload digital assets. If the entity selects to upload digital assets, the self registration pages shown in operations 422, 424 and 426 may be provided. Such self registration pages may allow the entity to upload digital assets with which it is associated.

For instance, the digital assets may be uploaded to a catalog of digital assets. The self registration pages may also provide an upload wizard for assisting the entity in uploading digital assets. Still yet, the self registration pages may provide information associated with a rule set that is applied to at least one of the digital assets. In one embodiment, the rule set may initially be a default rule set prior to any configuration performed by the entity. As an option, the self registration pages may even allow an entity to specify an associated rule set in conjunction with the uploading of any digital assets.

Based on the information provided in the self registration pages, the entity may decide whether to apply such information to an interface for facilitating transactions with respect to the uploaded digital assets. Note decision 428. Specifically, the entity may select any number of digital assets within the catalog of digital assets to be made available, utilizing the interface, for purchase by potential buyers. Such selected digital assets may optionally be stored in a store database separate from the catalog of digital assets.

Thus, the entity may choose to configure such interface utilizing store set-up pages in operation 430, or may choose to accept the interface as it is currently provided. If the entity does not choose to make any changes to the interface the entity may be provided with an appropriate preview page in operation 432 which presents a preview of the interface and code for embedding the interface in any desired page capable of rendering such code.

In this way, the entity may utilize such code in controlling where associated digital assets are provided to potential buyers. Such preview page will be described in further detail with respect to FIG. 8 et al. In addition, another page in operation 434 may be provided to display the catalog of all digital assets that have been uploaded and their associated rule sets. Thus, an interface set-up flow is provided by which an entity is capable of customizing an interface for facilitating transactions with respect to any digital assets associated with such entity.

FIG. 5 shows a graphical user interface (GUI) 500 for customizing a rule set associated with an interface that facilitates transactions involving at least one digital asset, in accordance with yet another embodiment. As an option, the GUI 500 may be implemented in the context of the architecture and environment of FIGS. 1-4. Of course, however, the GUI 500 may be carried out in any desired environment. It should also be noted that the aforementioned definitions may apply during the present description.

The GUI 500 is an interface capable of being utilized by an entity to customize a rule set associated with uploaded digital assets. Specifically, such rule set may be required prior to any uploaded digital assets being available for purchase utilizing the interface. Of course the rule set may be established at any time.

In one embodiment, each uploaded digital asset may be associated with a separate rule set. In another embodiment, a single rule set may be applicable to multiple uploaded digital assets. In addition, multiple rule sets may be applied in a priority order to any uploaded digital asset. Thus, if a highest priority rule set is deleted by the entity, a next highest rule set may be applied to the digital asset.

As shown, the rule set may specify a name of the rule set, a format for associated digital assets that the rule set accommodates (e.g., MP3, WAV, JPEG, WMA, DRM, etc.), countries in which the associated digital assets are available, retailers that may conduct transactions with respect to associated digital assets (e.g. specific web pages etc.), and/or a time period for which the rule set is applicable. In addition, the rule set may specify user permissions associated with the rule set, such as, for example, a number of times and/or a period of time for which a purchaser of the digital asset may view/play the digital asset, a number of times the digital asset may be duplicated by a purchaser and/or whether the digital asset may be copied to an external storage medium [e.g., compact disc (CD), digital video disc (DVD), memory stick, etc.].

Furthermore, the rule set may specify payment options capable of being utilized with respect to transactions of the associated digital assets. For instance, the payment options may define a wholesale price of associated digital assets, a payment method capable of being made with respect to the digital assets (e.g. PAYPAL®, credit card, e-check, bank transfer, gift cards, coupons, promotion codes, etc.) and/or the method by which a publisher of the digital asset may be paid. For example, if the publisher of the digital asset is separate from the entity, the rule set may specify that the entity will pay the publisher any applicable fees associated with any transactions made with respect to an associated digital asset. Of course, it should be noted that the rule set may specify any desired rules capable of being associated with digital asset transactions.

FIG. 6 shows a method 600 for registering a digital rights holder, in accordance with one embodiment. As an option, the method 600 may be implemented in the context of the architecture and environment of FIGS. 1-5. Of course, however, the method 600 may be carried out in any desired environment. It should also be noted that the aforementioned definitions may apply during the present description.

As shown in operation 602, a request from one of a plurality of entities which has an interest in at least one corresponding digital asset is received utilizing a network (e.g., see, for example, any of the networks 102 of FIG. 1, etc.). The request may be, for instance, a request to set-up an account for generating an interface for facilitating transactions involving corresponding digital assets. Of course, the request may include any request associated with generating such an interface.

Based on the request, an eligibility of entity is automatically verified (possibly utilizing the network), as shown in operation 604. The verification may include verifying a name, address, phone number and/or social security and/or Federal Tax I.D. number, of the entity making the request. Furthermore, the verification may include verifying any interest the entity may have in digital assets, Just by way of example, such verifications may optionally be performed utilizing a web site capable of making such verifications (e.g., LexisNexis, credit reporting web sites, etc.).

As an option, such verification may further include associating a risk level with the entity. For instance, such risk level may be based on a ratio of information that could be verified against information that could not be verified. Based on the verification of operation 604 an interface may then conditionally be provided to the entity for facilitating transactions involving the at least one digital asset. See operation 606. Just by way of example the interface may be provided based on the risk level associated with the entity. In particular, entities with a risk level higher than a predefined threshold may not be eligible for automatic registration, and may therefore be required to call customer service in order to register.

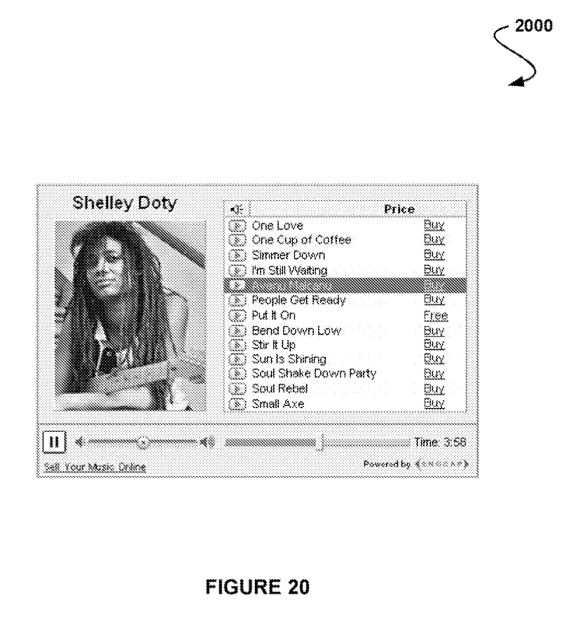

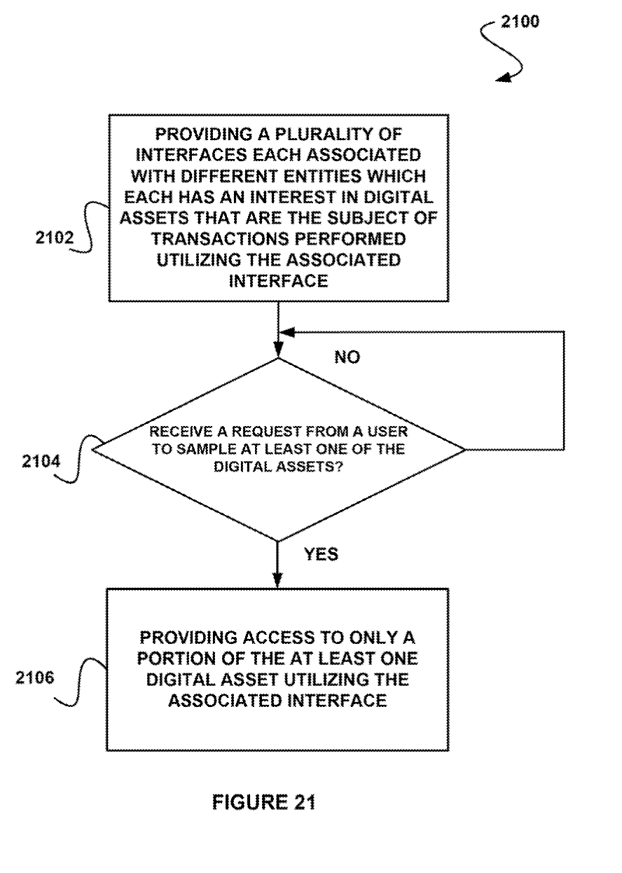

As another option the automatic account registration may require an entity to accept a click-through license agreement. For instance, the entity may be required to license all or a portion of its digital assets. In this way, sample selections of an entity's digital assets may be provided to potential purchasers. Such samples will be described in further detail with respect to FIGS. 20 and 21.

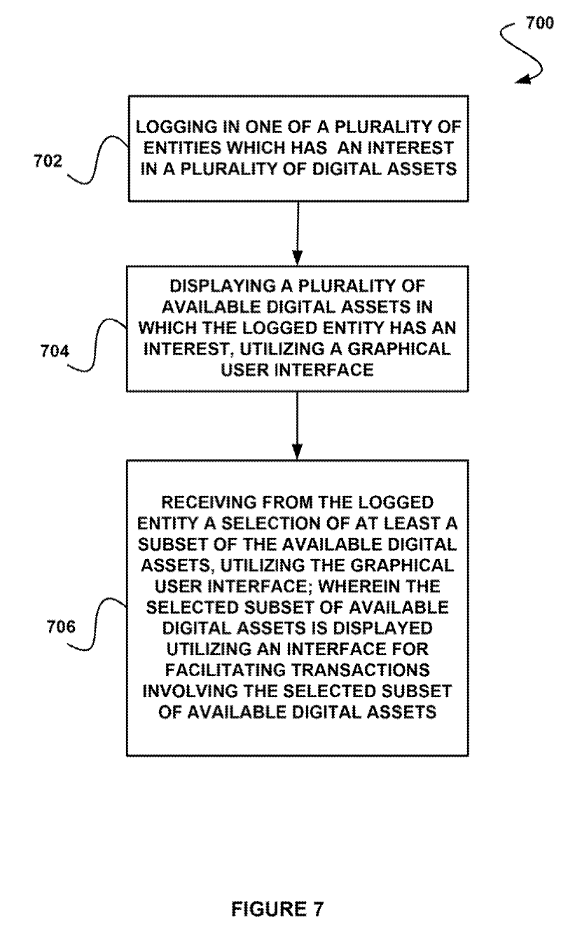

FIG. 7 shows a method 700 for generating an interface that facilitates transactions involving at least one digital asset in accordance with a user selection, in accordance with another embodiment. As an options the method 700 may be implemented in the context of the architecture and environment of FIGS. 1-6. Of course, however, the method 700 may be carried out in any desired environment. It should also be noted that the aforementioned definitions may apply during the present description.

As shown in operation 702 one of a plurality of entities which has an interest in a plurality of digital assets is logged-in. The entity may log-in utilizing a username and password provided during an account registration, such as that described above with respect to FIG. 4. Furthermore, the entity may log-in with respect to an account registration interface. Of course, the entity may log-in utilizing any desired interface.

A plurality of available digital assets in which the logged entity has an interest may then be displayed utilizing a graphical user interface, as shown in operation 704. Just by way of example, such available digital assets may include any digital assets that have been uploaded by the entity. See FIG. 4 for example. In addition, the available digital assets may be displayed based on a query of a digital asset library database (like the one mentioned above with respect to FIG. 1), and or any other data structure capable of storing digital assets. Furthermore, the graphical user interface may include any interface capable of displaying any available digital assets. For instance, more information on exemplary interfaces will be set forth in greater detail during reference to FIGS. 8-10.

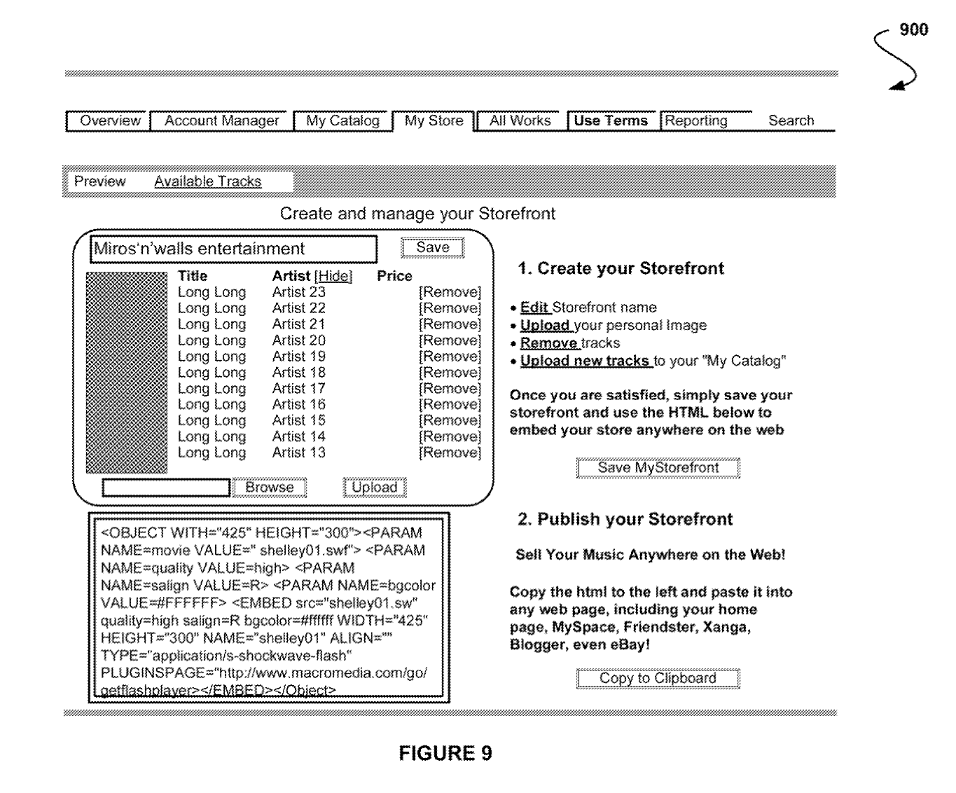

A selection of at least a subset of the available digital assets is then received utilizing the graphical user interface, as shown in operation 706. The subset may include any number of the available digital assets. In particular, as shown in FIGS. 8 and 9, the subset may be received utilizing “remove” links associated with available digital assets. The entity may select a “remove” link in order to remove an associated digital asset from the available digital assets. Thus, such removed digital asset may be removed from the display and/or from a digital asset library database.

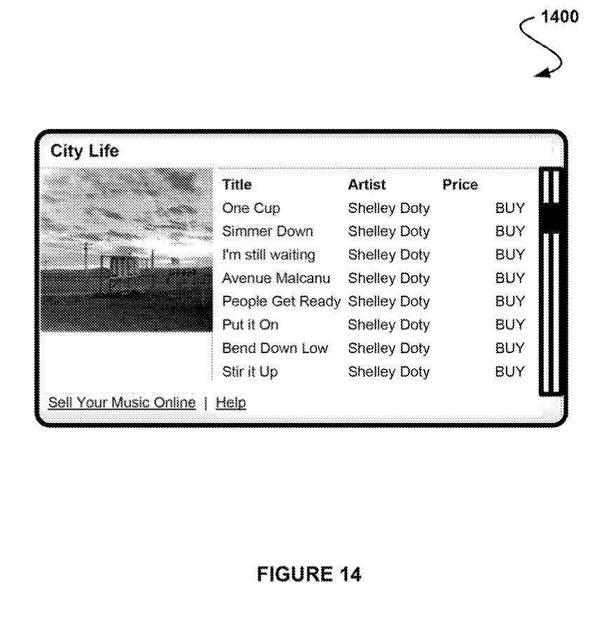

Still yet, as also shown in operation 706, the selected subset of the available digital assets may be displayed utilizing an interface for facilitating transactions involving the selected subset of the available digital asset. More information regarding an exemplary interface associated with such functionality will be set forth during reference to FIG. 14.

FIG. 8 shows a GUI 800 for generating an interface that facilitates transactions involving at least one digital asset, in accordance with yet another embodiment. As an option, the GUI 800 may be implemented in the context of the architecture and environment of FIGS. 1-7. Of course, however, the GUI 800 may be carried out in any desired environment. It should also be noted that the aforementioned definitions may apply during the present description.

As shown, the GUI 800 may include an interface generation/editing section, a preview section, and a publish section. Specifically, the interface generation/editing section may provide links that an entity may select to edit the interface that facilitates transactions involving at least one digital asset, along with any digital assets associated therewith. In addition, the interface generation/editing section may allow a user to customize a color and/or template associated with the interface.

Furthermore, the preview section may provide an entity with a sample of the look-and-feel of the interface including, for example, a screen shot of the interface. In this way, the entity may choose to utilize the generation/editing section along with options in the preview section to change anything displayed in the preview section.

The preview section may optionally include a link for editing a name of the interface. In use, the name of the interface may include a default name (e.g. the name of the entity on the associated account, etc.), however an entity may utilize such link to customize the displayed name. The preview section may also include a link for uploading an image that may be displayed within the interface. Still yet, the preview section may include a column that lists digital assets according to title that are available for an associated transaction.

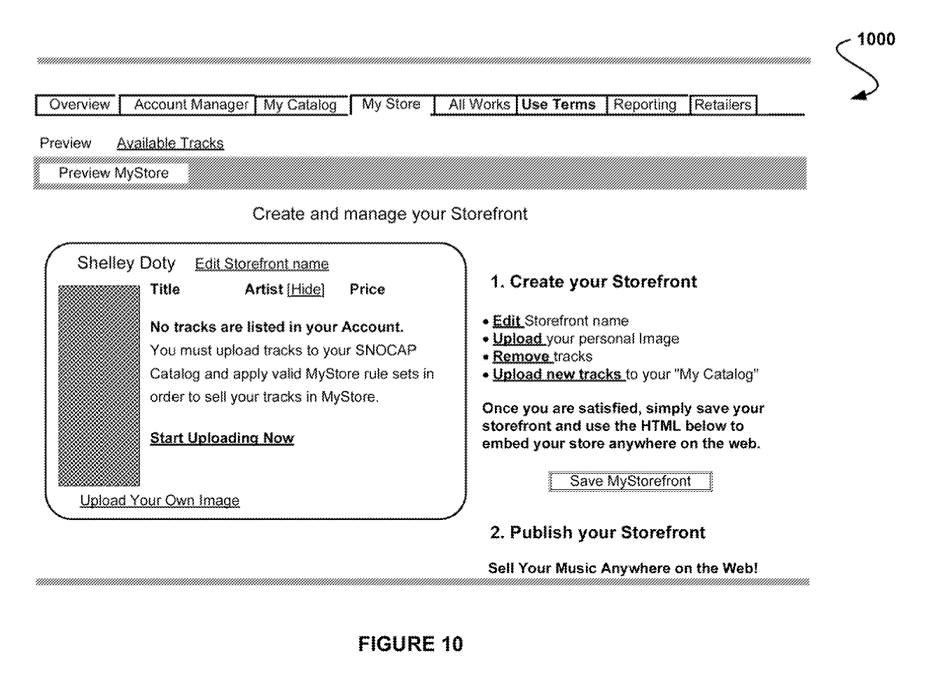

For example, such list of digital assets may include digital assets that have been uploaded by the entity and that have rule sets associated therewith. If no such digital assets are available, the preview section may include a notice with information on how to populate the associated interface. See FIG. 10 for an example 1000 of a preview section where no digital assets are available.

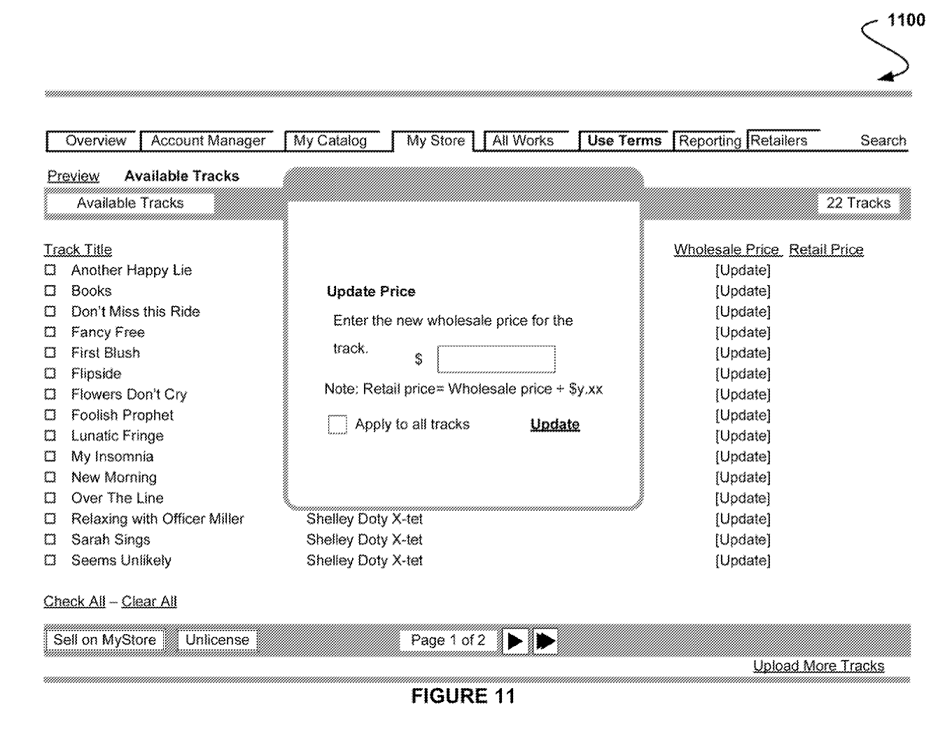

Additionally, the preview section may optionally include a column that lists artists associated with each available digital asset. As shown, an entity may hide such list of artists, such as for example when the artists are redundant for all available digital assets. The preview section may also include a column that lists prices associated with each available digital asset. Such prices will be described in further detail with respect to FIG. 11. Moreover, there may be a limit on the number of digital assets that may be displayed in the preview section, and therefore the interface. Thus, removal links may be provided in association with each available digital asset such that the entity may select to remove a digital asset from the available digital assets.

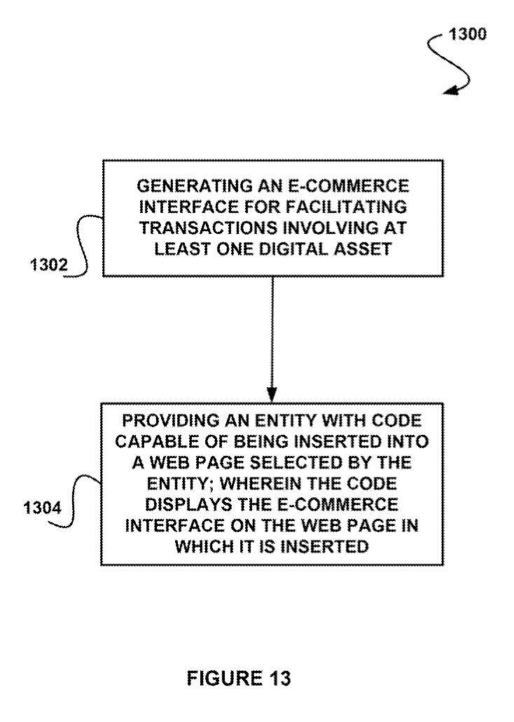

As another option, the preview section may allow the entity to customize the order to available digital assets listed. For example, the entity may be allowed to drag-and-drop the listed available digital assets. Also, the interface generation/editing section may include a “save” button that allows the entity to save any changes made to the preview section and therefore the interface. Based on the preview section, code may be provided to the entity that can be copied and pasted into an associated code editor. One optional embodiment of such code will be described in further detail with respect to FIG. 13.

FIG. 11 shows a GUI 1100 for updating a price of a digital asset, in accordance with one embodiment. As an option, the GUI 1110 may be implemented in the context of the architecture and environment of FIGS. 1-10. Of course, however, the GUI 1100 may be carried out in any desired environment. It should also be noted that the aforementioned definitions may apply during the present description.

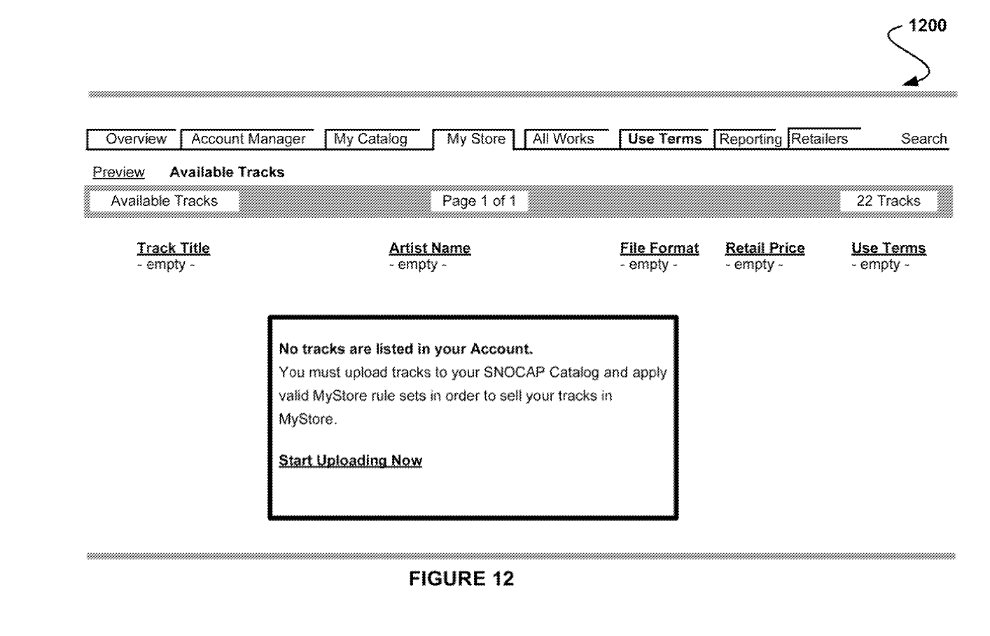

The GUI 1100 includes an interface in which available digital assets are displayed. For example, the GUI 1100 may be provided upon selection of the “Available Tracks” link in the GUI 800 of FIG. 8. Again, such available digital assets may include digital assets that have been uploaded by the entity and for which a rule set is associated. If there are no available digital assets, a notice may be displayed instructing the entity on how to provide available digital assets. See FIG. 12 for one example 1200 of such a notice.

The GUI 1100 may provide a column listing the titles of all available digital assets, a column listing the artists of all available digital assets, a column listing wholesale prices of all available digital assets, and a column listing retail prices of all available digital assets. Specifically, the wholesale price may include a price defined by the entity. Furthermore, the wholesale price may be defined within a rule set. In an embodiment that is strictly optional, if multiple rule sets are applicable to a single digital asset, the rule set with the lowest set wholesale price may be applied to the digital asset.

As shown, the GUI 1100 may provide a link associated with each listed wholesale price, such that the entity may update a wholesale price for each available digital asset listed. As specifically illustrated, upon selecting such wholesale price update link, another GUI may be displayed which allows the entity to input the updated wholesale price. As also specifically illustrated, the entity may further check a box in order to apply the inputted wholesale price to all available digital assets listed.

Moreover, when an entity selects to update a wholesale price of an available digital asset, such updated wholesale price may be compared to all prices within existing rule sets, If the updated wholesale price matches a wholesale price within an existing rule set, such matching rule set may be applied to the digital asset for which the entity desires to update the wholesale price. If the updated wholesale price does not match any wholesale prices within existing rule sets, a new rule set may be generated with the updated wholesale price as a parameter. Furthermore, any remaining parameters within such generated rule set may include default parameters.

In addition, the retail price, as listed in the GUI 1100 may include the sum of the entity-specified wholesale price, any costs associated with a transaction of the digital asset and a profit for such transaction. Specifically, the costs may include any hard costs, download costs, and/or payment transaction costs associated with providing the interface that facilitates transactions involving at least one digital asset. As an option any profit received from a transaction may be shared with distribution partners (e.g. web sites, web retailers, etc.).

Still yet, the GUI 1100 may include an upload link. Thus, an entity may select such link and be provided with self registration pages for uploading digital assets. Note for example, the self registration pages described above with respect to FIG. 4.

Furthermore, the GUI 1100 may allow an entity to select a subset of available digital assets. Just by way of example, the entity may make such a selection by checking a check box associated with a digital asset. Of course, such selection may be made in any desired manner. The entity may then specify the subset as being digital assets to be made available for purchase by potential buyers. Thus, the entity may customize a subset of the available digital assets to be made available for sale.

As another option, the entity may specify the subset as being digital assets that are to be unlicensed. Specifically such unlicensing may include removing the digital assets in the subset of available digital assets from the group of uploaded digital assets. In addition, such unlicensing may include deleting any rule sets associated with any digital assets included in the subset of available digital assets.

FIG. 13 shows a method 1300 for providing code that is capable of displaying an e-commerce interface on a web page in which it is inserted, in accordance with one embodiment. As an option, the method 1300 may be implemented in the context of the architecture and environment of FIGS. 1-12. Of course, however, the method 1300 may be carried out in any desired environment. It should also be noted that the aforementioned definitions may apply during the present description.

As shown in operation 1302, an e-commerce interface is generated for facilitating transactions involving at least one digital asset. The e-commerce interface may include any of the interfaces described above with respect to FIGS. 3-12. In addition, an entity is provided with code capable of being inserted into a web page selected by the entity.

In use, such code displays the e-commerce interface on the web page in which it is inserted. Note operation 1304. In the context of the present description, such code may refer to any computer code segments capable of displaying the interface in conjunction with a web page.

For example, such code may include HTML, JavaScript, XML, and/or any other code capable of being rendered within a web page. In addition, the web page may include any network-accessible file (e.g. web site, e-mail, blog, etc.). Furthermore, the code may display the e-commerce interface on the web page by rendering code which itself displays the e-commerce interface, by displaying a copy e-commerce interface that is linked to a master e-commerce interface, by pulling a copy of an e-commerce interface from a master e-commerce interface, etc.

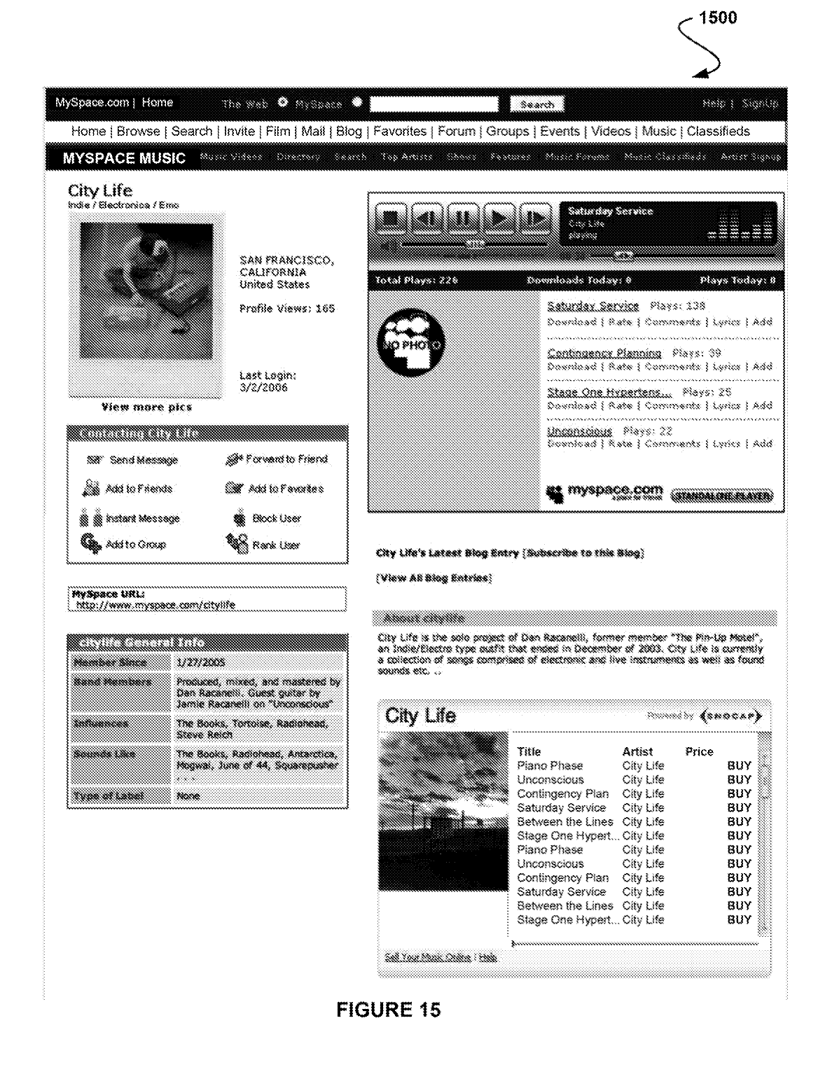

FIG. 14 illustrates an e-commerce interface 1400 generated by code provided to an entity that is capable of being inserted into a web page. In addition, FIG. 15 shows an e-commerce interface 1500 that has been embedded within a web page.

As an option, the code may include a link to a store database that contains information on a current state of the e-commerce interface. Thus, the embedded code may automatically be updated each time it is run according to the information stored in the store database, such that any changes made to the e-commerce interface by the entity may be displayed accordingly. Table 1 illustrates just one example of HTML code that may be provided and embedded within a web page.

TABLE 1
<object width=“425” height=“300”>
<param name=“movie” value=“http://store.dev.snocap.com/s/T3-31324-
AWTCN32VRR-Z.swf” />
<embed src=“http://store.dev.snocap.com/s/T3-31324-AWTCN32VRR-Z.-
swf”
width=“425” height=“300” type=“application/x-shockwave-flash”/>
</object>

Of course, such code is set forth for illustrative purposes only and should not be construed as limiting in any manner whatsoever.

In this way, the user may place the e-commerce interface in any desired web page by simply copying the provided code and pasting the code in a web page. Thus, the entity may control where its digital assets may be purchased from potential buyers. Just by way of example, the code may be embedded within a plurality of separate web pages, such that the e-commerce interface may be displayed on the plurality of separate web pages. In particular, multiple instances of the e-commerce interface may exist at different locations on a network, such that transactions associated with digital assets may take place at each of the different locations, Still yet, each e-commerce interface or associated logic may provide a list all locations where the same e-commerce interface is located.

It should be noted that the present embodiment (as well as the others set forth herein) may not, in some embodiments, be necessarily limited to the sale of digital assets. For example the present embodiment may be used for selling, auctioning, etc., any type of goods and/or services. In such embodiments, sellers, auctioneers, etc. may post goods and/or services using mutiple interfaces in the aforementioned manner, thereby obviating the need to use a single interface (shared with other sellers, etc.) whereby potentially purchasers, bidders, etc. may be subjected to competing goods and/or services.

As a further option, an entity may receive reports based on such embedded e-commerce interfaces. In particular, the entity may receive individual reports for each embedded e-commerce interface and/or aggregated reports for an e-commerce interface that exists at multiple different locations on a network. Such reports may provide locations for each embedded e-commerce interface and/or usage and/or sale information according to each location. Table 2 provides a list of type of information that may be included within the reports.

TABLE 2

| | |
|---|---|
| 1. | Total downloads of all digital assets across all locations |
| 2. | Total downloads of all digital assets for each location |
| 3. | Number of downloads according to digital asset across all locations |
| 4. | Gross revenue generated across all locations |
| 5. | Net revenue generated across all locations |
| 6. | Gross revenue according to digital asset across all locations |
| 7. | Net revenue according to each digital asset across all locations |
| 8. | Gross revenue generated for each location |
| 9. | Net revenue generated for each location |

Of course, such table is set forth by way of illustration only, such that any and/or all of such information types may be included in the reports along with any additional information capable of being reported in association with an embedded e-commerce interface,

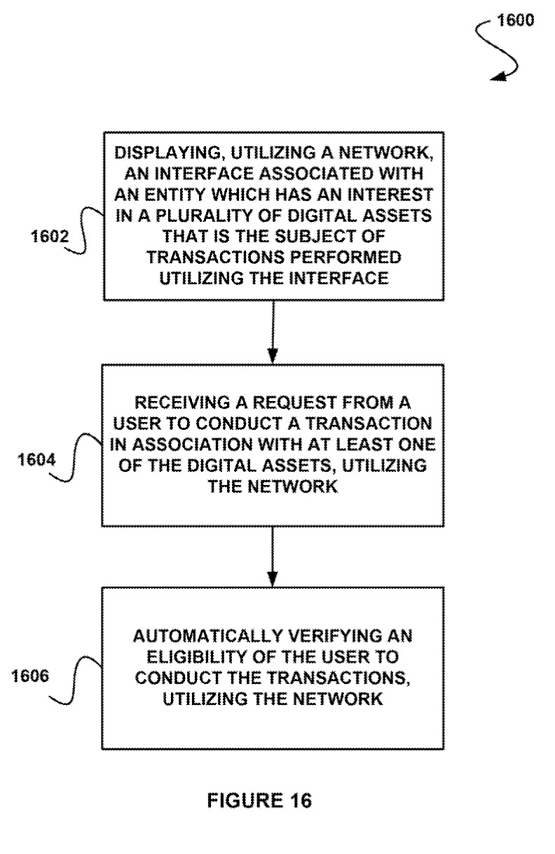

FIG. 16 shows a method 1600 for verifying a buyer to purchase a digital asset, in accordance with one embodiment. As an option, the method 1600 may be implemented in the context of the architecture and environment of FIGS. 1-15. Of course, however, the method 1600 may be carried out in any desired environment. It should also be noted that the aforementioned definitions may apply during the present description.

As shown in operation 1602, an interface associated with an entity which has an interest in a plurality of digital assets that is the subject of transactions performed is displayed utilizing an interface. The interface may include, for example, the e-commerce interface described above with respect to FIGS. 13-15.

A request to conduct a transaction in association with at least one of the digital assets may then be received from a user, utilizing the network. Note operation 1604. For example, the user may select a buy option in association with at least one digital asset from the interface. Further, the user may select a buy option for a plurality of digital assets to be purchased in a single transaction. Of course, any type of transaction may be initiated by the user.

In addition, an eligibility of the user to conduct the transactions may automatically be verified utilizing the network, as shown in operation 1606. For instance, the eligibility may he verified by matching the user to an associated user account. If not found, the user may be required to create a user account in order to conduct any transactions with respect to digital assets of any entity. In this way, a single account associated with a user may be utilized by the user to initiate transactions for any interfaces associated with any entities having an interest in digital assets. Such user account may allow payments to be aggregated over predefined periods of time for transactions associated with any number of digital assets and/or entities.

In one instance the user may be prompted to log-in to a user account upon making the request to conduct the transaction if the user's eligibility cannot be verified, if the user does not have a user account, the user may be prompted to generate such a user account. The user account may be generated on-line by the user providing user information, such as a name, address, phone number, e-mail, payment account (e.g. PAYPAL®, credit card, bank account routing and number information, etc.) and/or any other information capable of being associated with the user.

During account set-up, the user may also be required to agree to a click-through licensing agreement with respect to digital assets available for purchase. Of course, it should be noted that the eligibility of the user may be verified in any desired manner. In this way, a user may be verified prior to being allowed to conduct any transactions with respect to digital assets.

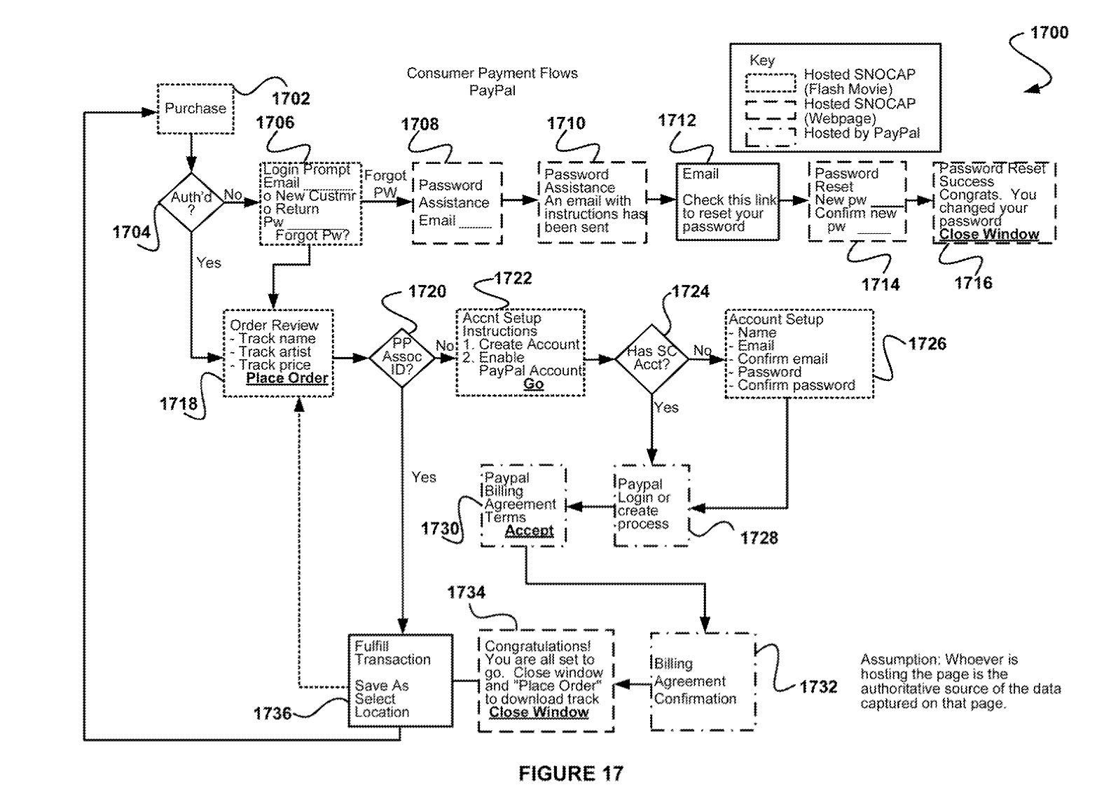

FIG. 17 shows a flow chart 1700 for purchasing a digital asset, in accordance with one embodiment. As an option, the flow chart 1700 may be implemented in the context of the architecture and environment of FIGS. 1-16. Of course, however, the flow chart 1700 may be carried out in any desired environment. It should also be noted that the aforementioned definitions may apply during the present description.

As shown in operation 1702, a user selects a digital asset to purchase from all interface provided by an entity with an interest in the digital asset. As described above with respect to FIG. 16, such selection may be made utilizing a buy option in association with at least one digital asset from the interface. Of course, the transaction may be initiated by the user in any desired manner.

It is then determined whether the user is authorized, as shown in decision 1704. As described above with respect to FIG. 16, such authorization may be verified by matching the user to a user account, etc. If the user is not determined to be authorized in decision 1704 the user may be prompted to log-in to a user account, as shown in operation 1706.

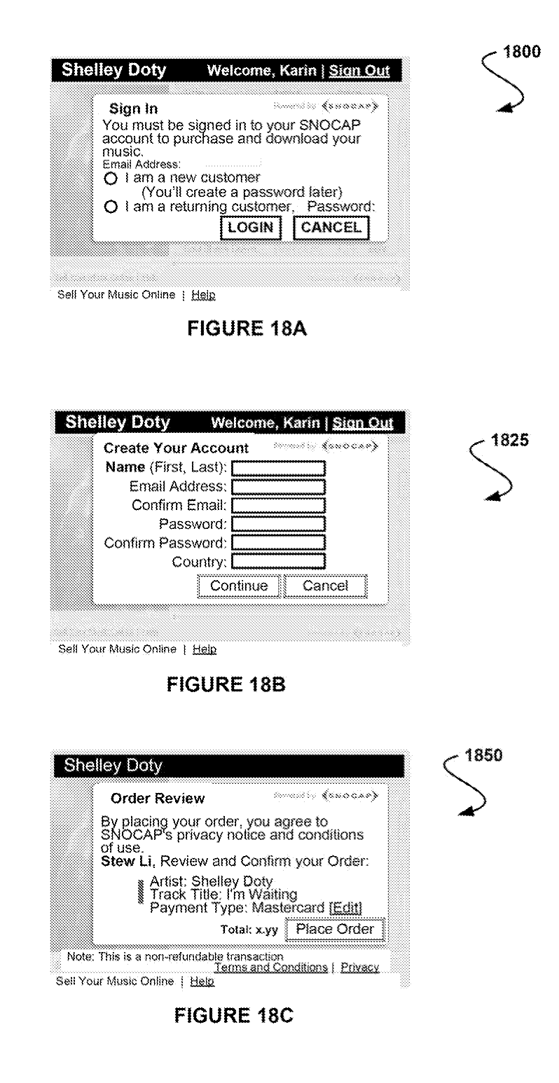

See FIGS. 18A and 18B for example interfaces 1800, 1825 that may be utilized in presenting such prompts, Specifically, the log-in prompt may include an e-mail field, existing user and new user radio buttons, a password field and/or a forgotten password link. Of course, the log-in prompt may include any desired information.

If the user does not have log-in information, the user may select to create a new user account. An account set-up page (not shown) may then be presented to the user. Such accounts set-up page may include, for example, an e-mail address field that may optionally be pre-populated from the log-in page in operation 1704, a confirmation email address field, a password field, a confirmation password field, a country of residence fields and/or any other fields capable of receiving information associated with the user.

Optionally, the user may be provided with password assistance if the user cannot remember a password associated with the user's user account. Note operation 1708. For example, the password assistance may be provided upon the user entering an e-mail address associated with the user account.

Upon entity of the e-mail address, a page may be displayed to the user informing the user whether the e-mail is associated with a valid user account, as in operation 1710. Also, the page displayed in operation 1710 may inform the user that an e-mail has been sent to the e-mail address entered. An e-mail may be sent to the user's entered e-mail, as shown in operation 1712.

Such e-mail may include a secure link to a page that prompts the user to input a new password and confirm the new password to be associated with the user's account. Note operation 1714. The user may then be informed that the new password is in effect, as in operation 1716.

As one option, the user may be automatically authorized to purchase digital assets upon the user inputting the new password and therefore the method may proceed to operation 1718. As another option, the user may be required to re-select a digital asset to purchase from an interface provided by an entity with an interest in the digital asset, and therefore the method may return to operation 1702 in order for the purchase to proceed. From operation 1702, the user may automatically be determined to be authorized in decision 1704. If the user is not automatically determined to be authorized in decision 1704, the user may again be prompted for log-in information in operation 1706.

After the use is authorized, the user may be presented with an order review page, as shown in operation 1718. Such order review page may list any digital assets selected to be purchased by the user, along with information associated with such digital assets. The information may include a title of the digital assets to be purchased, an artist of the digital assets to be purchased and a total price for all of the digital assets to be purchased. In addition, such information may be received, at least in part, from a store database containing information associated with available digital assets. FIG. 18C shows one exemplary order review page 1850 capable of being provided to a user.

From the order review page, the user may then select a link on such page to proceed with the order. The user's payment information may then be verified, as shown in decision 1720. Such payment information may include payment information associated with the user's account, payment information entered by the user and/or any other type of payment information capable of being verified. As an option the users payment information may include a PAYPAL® account, a credit card number, a bank account number with routing information, a gift card number, a coupon number, etc. Furthermore, such payment information may include whether a payment account is capable of presenting sufficient funds to complete the transaction.

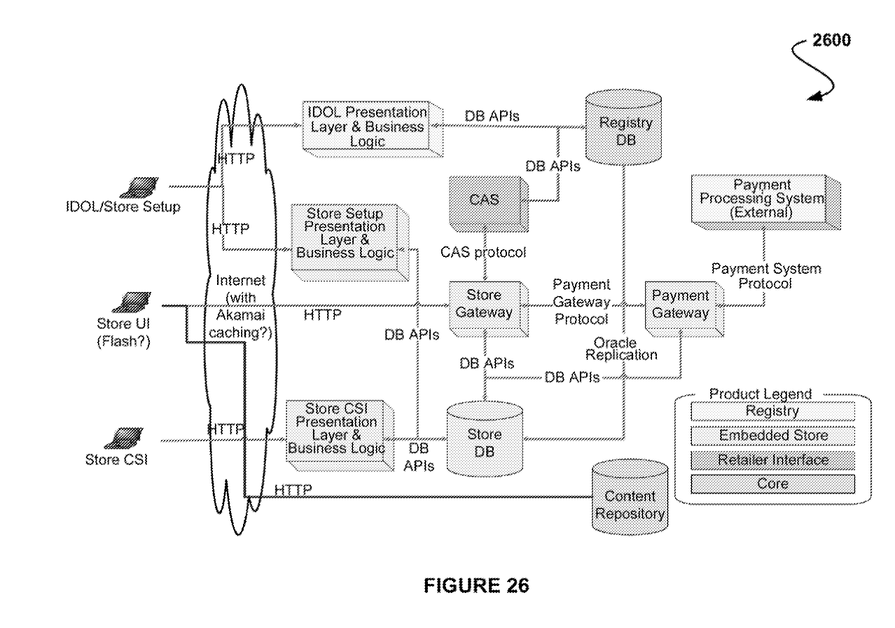

If the user's payment account information is verified in decision 1720, the user requested transaction is fulfilled. Note operation 1736. Such transaction may be fulfilled by charging the user for any digital assets selected by the user to be purchased utilizing the payment information. One example of a payment system will be described in more detail with respect to FIG. 26.

If the user's payment account information is not verified in decision 1720, the user may be provided with a payment account set-up page, as shown in operation 1722. The account set-up page may determine whether the user has a credit card account and/or any other type of bank account, as seen in decision 1724. If the user does have such an account, the user may be prompted to log-in to a payment system (e.g. PAPAL®, etc.) or create a payment process utilizing such account, as shown in operation 1728.

If the user does not have such an account, the user may be prompted to set-up an account by inputting the user's name, e-mail, password and/or any other information capable of being associated with the user. Note operation 1726. One example 1825 of such account set-up prompt is shown with respect to FIG. 18B. Upon creation of the account, the user may then be prompted to log-in to a payment system or create a payment process utilizing the payment system, as shown in operation 1728.

In addition, the user may be required to accept a click-through agreement associated with the payment system as shown in operation 1730. Such agreement may include a billing agreement by which the user will be billed for any payments made on the user's behalf by the payment system. Once the user accepts such agreement, a confirmation of the agreement may be presented to the user, as in operation 1732. As an option, operations 1726-1732 may be hosted by the payment system. In operation 1734, the user may also be presented with a notice informing the user that the purchase may be made.

The user may then be allowed to complete a purchase selection, and such purchase transaction may be fulfilled, as shown in operation 1736. Once the purchase transaction is fulfilled in operation 1736, the user may be allowed to receive the purchased digital asset(s). Such digital asset(s) may be downloaded, emailed as an attachment and/or received by the user in any desired manner. For example, if the digital asset(s) is to be downloaded, the user may be prompted with an interface for saving the digital asset(s) to the user's computer.

The received asset may then be played and/or viewed by the user on the device to which the user downloaded the digital asset. In addition, once the purchase transaction is fulfilled in operation 1736, an e-mail confirmation may be sent to the user. See operation 1732.

Such e-mail confirmation may optionally include the title of the digital asset purchased, the artist associated with the purchased digital asset, a purchase amount, a date of the purchase, a location of the interface by which the purchase was initiated (e.g. website URL, retail identification, etc.) and/or a link capable of being used to download the purchased digital asset. Specifically, such link may be associated with a download license that is provided for a predetermined amount of time, such that the link may be utilized only for such predetermined amount of time. Of course, any information associated with the user and/or purchase of the digital asset may be included in the confirmation e-mail.

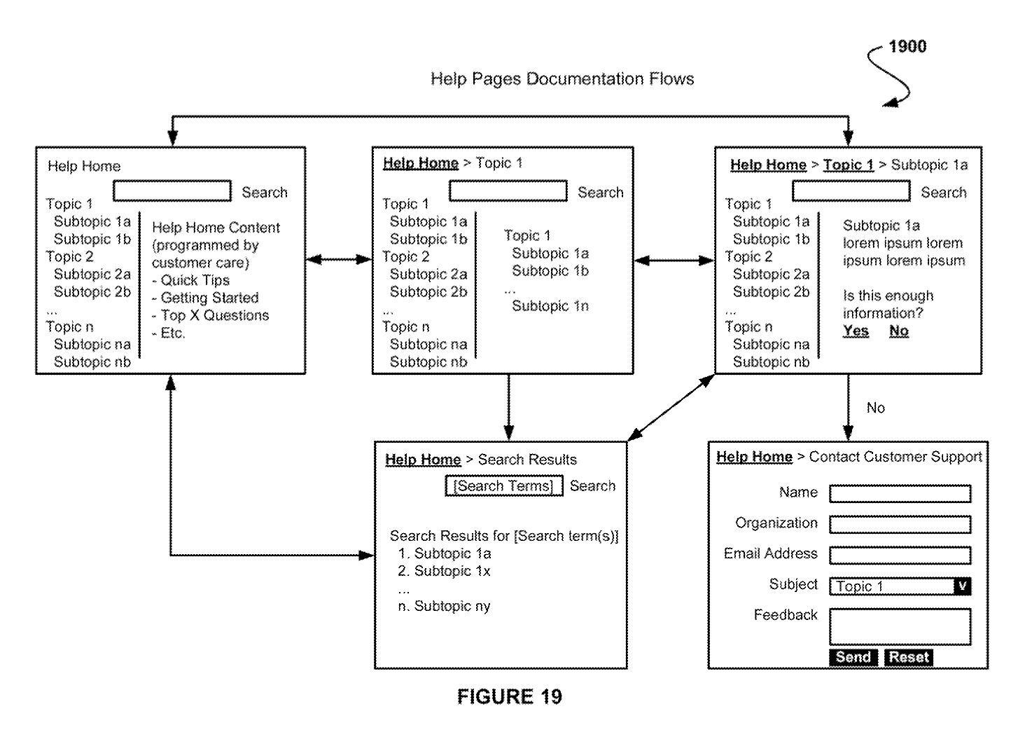

FIG. 19 shows a flow chart 1900 for help pages, in accordance with one embodiment. As an option, the flow chart 1900 may be implemented in the context of the architecture and environment of FIGS. 1-18. Of course, however, the flow chart 1900 may be carried out in any desired environment. It should also be noted that the aforementioned definitions may, apply during the present description.

The help pages may include any type of pages capable of being displayed to a user and capable of providing information to answer a user's and/or entity's questions in any form (e.g. web pages, downloaded file pages, etc.). The help pages may include a search field capable of allowing a user to search for specific terms within the help pages. The help pages may also be structured by topic, such that specific information may be presented upon selection of a general topic associated with the specific information.

Additionally, the help pages may include “breadcrumbs” for allowing a user to navigate within a hierarchy of information (e.g. topics and subtopics). The help pages may also include information that is ordered within each general topic. Still yet, the help pages may include a feedback option that allows a user to provide feedback (e.g. comments, additional questions not answered by the help pages, etc.). For instance, the feedback may be input by the user into a feedback form associated with the help pages. Such form may optionally include a user/entity name field an organization field associated with the user/entity an e-mail field associated with the user/entity, a subject field associated with the feedback and/for a comment field.

Help pages for users may be provided utilizing links incorporated within interfaces, which are associated with entities and which are utilized for facilitating transactions for digital assets. Table 4 shows exemplary information that may be included within the help pages for users.

TABLE 4

| | |
|---|---|
| 1. | General questions |
| 2. | Billing support |
| 3. | Technical support (e.g. download, payment issues, etc.) |
| 4. | Information for entities interested in creating an interface |

Of course, such information is just by way of example only, and is not to be construed as limiting in any manner.

Help pages for entities may be provided utilizing a page associated with creation/modification interface pages. For example, the help pages may be associated with an interface overview page, such as the overview page 414 described above in FIG. 4. Table 5 shows exemplary information that may be included within the help pages for entities.

TABLE 5

| | |
|---|---|
| 1. | General questions |
| 2. | Account set-up information |
| 3. | Selling information |

Again, such information is just by way of example only, and is not to be construed as limiting in any manner.

Furthermore, help pages may be provided for customer service representatives. Such help pages may include billing information, transaction information received from a database (e.g, confirmation of payment, payment amount time of purchase, digital asset purchased, artist, location purchased from, download status, etc.), refund information and/or any other information capable of providing help to customer service representatives. Customer services representatives may also be allowed to insert comments in association with purchases stored in a database, such that comments associated with any help provided may be recorded.

Table 6 illustrates information that may be provided to customer service representatives utilizing help pages.

TABLE 6

| General FAQs | Billing Support | Technical Support |
|---|---|---|
| How To's | Payment Issues | Store/Player Operating Issues |
| | Chargebacks & Refunds | Troubleshooting tips |
| | Duplicate Transactions | Links to Flash plug-in |
| File Formats Supported | Trust & Safety | Downloading Issues |
| | Fraud | Purchase email |
| | Phishing (http://www.paypal.com/cgi- | confirmation includes link |
| | bin/webscr?cmd=_help- | to download (48 hr |
| | ext&eloc=0&loc=1764&source_page=_home&flow=) | license) |
| | Username & Password Security | Still having issue, |
| | SSL Transactions | customer care sends new |
| | | link to download (48 hr |
| | | license) |
| | | Still unable to download, |
| | | refund for the transaction |
| Billing & Payments | Questions related to Credit/Debit Card Bill/ | Sample clip playing issue |
| Clearly message that | Statement | Troubleshooting tips |
| SNOCAP is the | | |
| merchant of record (to | | |
| reduce minimize | | |
| consumers contacting | | |
| artist directly) | | |
| Are you interested in selling | Contact/Email Form | General Troubleshooting Tips |
| your music? | Auto-populate with support topic | |
| Link to the Store promo | | |
| page | | |
| Already a | | |
| member? | | |
| New to | | |
| SNOCAP. | | |
| Contact/Email Form | | Contact/Email Form |
| Auto-populate with | | Auto-populate with |
| support topic | | support topic |
| Note: You are | | |
| contacting SNOCAP | | |
| customer care, not the | | |
| artist. | | |

FIG. 20 shows a GUI 2000 for purchasing and previewing available digital assets in accordance with one embodiment. As an option, the GUI 2000 may be implemented in the context of the architecture and environment of FIGS. 1-19. Of course, however, the GUI 2000 may be carried out in any desired environment. It should also be noted that the aforementioned definitions may apply during the present description.

The GUI 2000 may include any interface associated with an entity that provides transaction capabilities with respect to digital assets. As shown, the GUI 2000 includes a list of digital assets, their associated prices, and an option for a user to buy any of the digital assets. In addition, the GUI 2000 includes an integrated presentation module for presenting the digital assets listed. As specifically shown, the GUI 2000 provides a network based media player for a user to listen to the digital assets. In one embodiment, such integrated presentation module may be configured to only present a limited portion (e.g. sample) of digital assets.

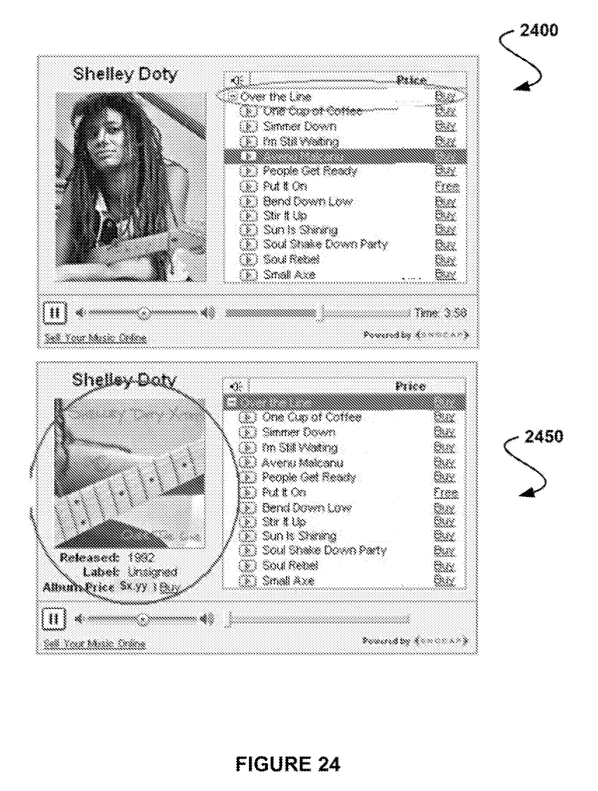

In addition, the GUI 2000 may optionally provide collections of digital assets that may be purchased as a collection. Furthermore, the GUI 2000 may display an image for each collection. Thus, if the digital assets are sound recordings, the GUI 2000 may provide entire albums for purchase, and such albums may be displayed with an associated image. See FIG. 24 for two examples of GUIs 2400 and 2450 that provide for the purchase of collections of digital assets.

In this way the user may receive a preview of the digital assets, but may only be able to receive the full digital assets upon purchase of the same.

FIG. 21 shows a method 2100 for providing a preview of available digital assets in accordance with another embodiment. As an option the method 2100 may be implemented in the context of the architecture and environment of FIGS. 1-19, and particularly in the context of the GUI 2000 of FIG. 20. Of course, however, the method 2100 may be carried out in any desired environment. It should also be noted that the aforementioned definitions may apply during the present description.

As shown in operation 2102, a plurality of interfaces are provided, each associated with different entities which each has an interest in digital assets that are the subject of transactions performed utilizing the associated interface. Of course, such interface may be implemented in the context of any of the foregoing figures. See FIG. 20, for example.

During use of such a framework, a request is received from a user to sample at least one of the digital assets utilizing the associated interface. See decision 2104. The request may be received by a user selecting a sample link associated with a digital asset. In addition, such sample may include a presentation of a limited portion of the digital asset [e.g. 10, 20, 30, or 60 second sound/video clip (or any other amount, for that matter), paragraph excerpt, etc.]. Thus, in response to the request, access to only a portion of the at least one digital asset is provided utilizing the associated interface. In use, the portion of the digital asset may be presented to the user utilizing any media device capable of presenting the digital asset.

As an option, the sample may be stored within a catalog database. Thus, when an entity uploads a digital asset to the catalog database, a sample may automatically be created for the digital asset. In addition when the entity makes the digital asset available utilizing the interface, the sample may be saved in a store database along with the available digital asset.

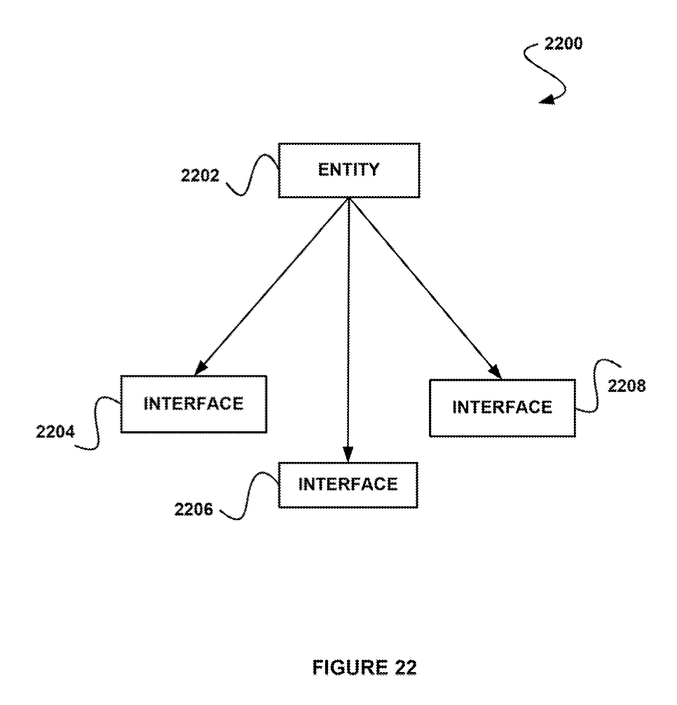

FIG. 22 shows a system 2200 in which an entity is associated with a plurality of interfaces, in accordance with one embodiment. As an option, the system 2200 may be implemented in the context of the architecture and environment of FIGS. 1-21. Of course, however, the system 2200 may be carried out in any desired environment. It should also be noted that the aforementioned definitions may apply during the present description.

As shown, a plurality of interfaces 2204, 2206 and 2208 are all associated with the same entity 2202. For example, such plurality of interfaces may be displayed at different locations on a network (e.g. separate web sites etc.).

In one embodiment, the plurality of interfaces may all provide the same available digital assets. In another embodiment, the plurality of interfaces may each provide a different subset of digital assets. In one example, each location may only provide digital assets associated with one particular artist. In another example, each location may only provide digital assets associated with a particular genre. In this way, the entity may control the availability of digital assets according to a location of their associated interface.

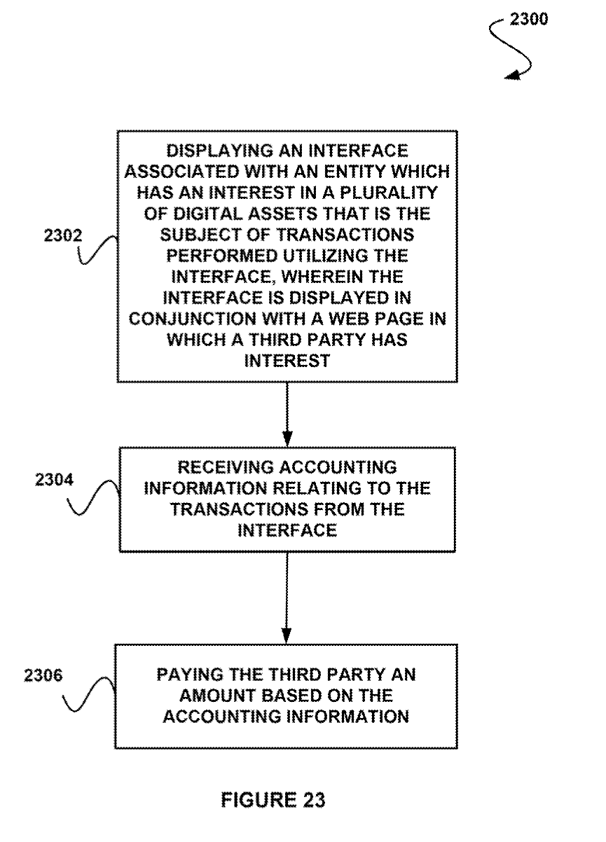

FIG. 23 shows a method 2300 for displaying an interface in conjunction with a web page in which a third party has interest, in accordance with one embodiment. As an option, the method 2300 may be implemented in the context of the architecture and environment of FIGS. 1-22. Of course, however, the method 2300 may be carried out in any desired environment. It should also be noted that the aforementioned definitions may apply during the present description.

As shown in operation 2302, an interface is displayed which is associated with an entity which has an interest in a plurality of digital assets that is the subject of transactions performed utilizing the interface. Of course such interface may be implemented in the context of any of the foregoing figures. See FIG. 20, for example.

As further shown the interface may be displayed in conjunction with a web page in which a third party has interest. The third party may include any on-line affiliate, on-line retailer, and/or any other party capable of displaying the interface in conjunction with a web page (and who is not the entity).

Thus the third party may host an interface within its own website without being the entity that has an interest in digital assets provided in the interface. As an option, the third party may be required to sign a license agreement prior to being allowed to provide such interface. In addition, the third party may only be allowed to provide digital assets that have been approved for such purpose by the entity. Just by way of example, such approval may be provided within rule sets associated with the digital assets.

In addition, accounting information relating to the transactions from the interface is received, as shown in operation 2304. Thus, accounting information associated with any transactions made with respect to the digital assets may be received. The accounting information may include a report of digital assets sold, total revenue from purchases and/or any other information capable of being associated with digital asset-related transactions provided within the interface. Still yet, the third party may be paid an amount based on the accounting information, as in operation 2306. Just by way of example, the third party may be paid a percentage of each digital asset sold and/or a percentage of all digital assets sold. In this way, third parties may be able to facilitate transaction with respect to digital assets owned by separate entities.

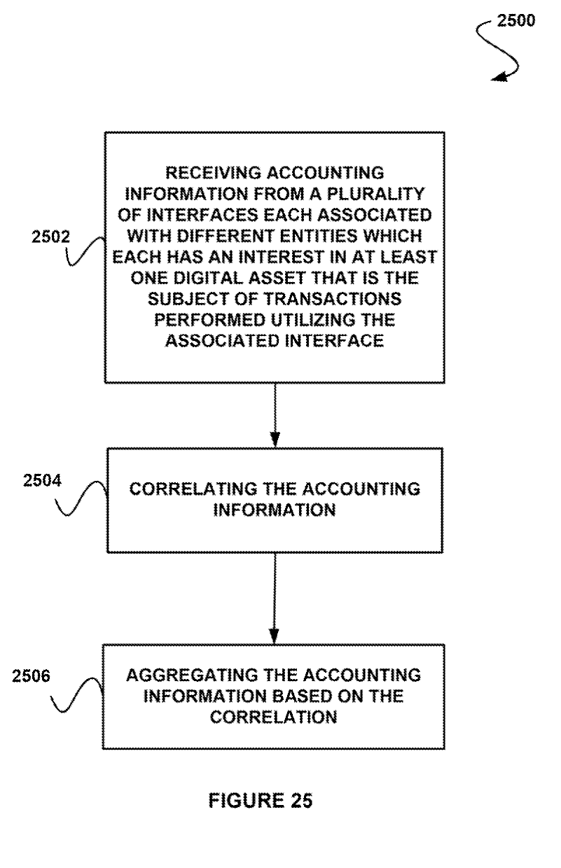

FIG. 25 shows a method 2500 for aggregating accounting information from a plurality of interfaces, in accordance with one embodiment. As an option, the method 2500 may be implemented in the context of the architecture and environment of FIGS. 1-24. Of course, however, the method 2500 may be carried out in any desired environment. It should also be noted that the aforementioned definitions may apply during the present description.

As shown in operation 2502, accounting information is received from a plurality of interfaces each associated with different entities which each has an interest in at least one digital asset that is the subject of transactions performed utilizing the associated interface. The accounting information may include, for example, information identifying digital assets sold, sellers of the digital assets, times of sale of the digital assets, and/or any other information capable of being associated with transactions associated with the digital assets.

In addition, the accounting information is correlated as shown in operation 2504. Such accounting information may be correlated in any desired manner. Just by way of example, the correlation may be based on all sales within a predetermined time period that are associated with a single seller. Furthermore the accounting information is aggregated based on the correlation. Note operation 2506. For instance, the accounting information may be stored in a database according to such correlation.

In this way, accounting information received from a plurality of interfaces may be organized. As an option, such aggregation may be used to reduce an amount of fees associated with a corresponding payment service. For example, if a service provider is charged a particular fee for each transaction, the present method 2500 may be used to aggregate transactions, thereby reducing a number of transactions and an associated payment charges.

FIG. 26 shows a system 2600 for generating interfaces that facilitate transactions involving at least one digital asset, in accordance with one embodiment. As an option, the system 2600 may be implemented in the context of the architecture and environment of FIGS. 1-25. Of course, however, the system 2600 may be carried out in any desired environment. It should also be noted that the aforementioned definitions may apply during the present description.

As shown, the system 2600 includes three interface applications (i.e. set-up interface application, a user interface application, and a customer service interface application). The set-up interface application may be any application that allows entities to upload digital assets, manage digital assets, and provide such digital assets for transactional purposes utilizing an interface. As shown, the set-up interface may connect to a registry component and a store set-up component utilizing Hypertext Transfer Protocol (HTTP).

The registry component may include a front-end application that transfers uploaded digital assets to a registry database. The registry component may generate pages presented in the user interface application described below. Specifically, it may invoke database application program interface calls to set and get values stored in the registry database. As an option, it may not access the store database. In addition, the registry database may store all data associated with uploaded digital assets and/or the entities associated with such digital assets.

The store set-up component may generate pages presented in the user interface application. It may invoke database application program interface calls to set and get values stored in the store database. As an option, it may not access the registry database. In addition it may be a separate application that works in close conjunction with the standard user interface. Thus, authentication between the two applications may be seamless and require no secondary prompting for credentials.

To achieve this, a single sign-on solution may be developed that associates a time-limited authentication token with the user session and passes the token between the two applications. The store application may validate the token using a custom single sign-on system (i.e. a database) shared by two applications. If a user attempts to access the store application directly (e.g. by following a bookmarked link), the user may be challenged for credentials. Additionally, the store set-up component may include a customer care service (e.g. customer service representatives) capable of looking up transactions and any data associated therewith. Such transactional data may be stored remotely, and may be accessed seamlessly by the store set-up component.

Furthermore, the store database may be a replicated view of the registry database. For example, it may use standard ORACLE® replication to keep a subset of the registry database content up-to-date. It may also contain additional information necessary for the store application, such as for example selling entities, buyers, accounting information, retail pricing, consumer account information and/or any information relating to transactions with respect to digital assets.

The user interface application may include a Flash application and/or any other type of application capable of facilitating transactions associated with digital assets. The user interface application may be in communication with a store gateway. In particular, the store gateway may provide the user interface application with data required for the user interface application to provide digital assets. In addition, the store gateway may process purchase requests made by users for digital assets.

The store gateway may include a server component that provides a scaleable HTTP connection to the user interface application. In addition, the store gateway may communicate with the client access server (CAS) to perform download authorization. It may also communicate with the payment gateway to charge and/or debit a user's account for an amount of a transaction. Still yet, the store gateway may obtain a purchase certificate to authorize a download. Additionally, the store gateway may interface with the store database using its database application program interfaces.

Thus, the store gateway may send purchase requests to a payment gateway. Thus, the payment gateway may provide an interface to the store gateway to allow purchase transactions to be recorded. In addition, it may provide purchase certificates. Further, the payment gateway may transcode purchase requests into an abstract form and forwards such abstract requests to third party payment processing systems. Once payment is secured by the third party payment processing system, the CAS may provide a download authorization certificate. The CAS may provide a real-time interface for retailer applications. It may provide sharing certificates, download preauthorization certificates, and download authorization certificates.

Moreover, the content repository may be in communication with the user interface application. It may serve audio files downloaded to the user interface application. It may also provide security to prevent unauthorized file downloads. To achieve scalability and availability, an edge-caching service, such as AKAMAI®, may be used to sit between the content repository and the consumer.

While various embodiments have been described above, it should be understood that they have been presented by way of example only, and not limitation. For example, any of the network elements may employ any of the desired functionality set forth hereinabove. Thus, the breadth and scope of a preferred embodiment should not be limited by any of the above-described exemplary embodiments, but should be defined only in accordance with the following claims and their equivalents.

What is claimed is:

1. A method, comprising:
receiving, utilizing a network, a request from one of a plurality of entities which each has an interest in at least one corresponding digital asset;
automatically verifying an eligibility of the entity; and
conditionally providing an interface for the entity for facilitating transactions involving the at least one digital asset, based on the verification.

2. The method of claim 1, wherein the entities are each selected from the group consisting of a person, a group of people, and a business.

3. The method of claim 1, wherein the digital asset is selected from the group consisting of video, audio, an image, a publication, lyrics, and a composition.

4. The method of claim 1, wherein the transactions include a purchase of the at least one corresponding digital asset.

5. The method of claim 1, wherein the request is for setting up an account for the entity.

6. The method of claim 1, wherein the verification includes verifying information associated with the entity.

7. The method of claim 6, wherein the information is selected from the group consisting of a name, an address, a phone number, a social security identifier, a federal tax identifier.

8. The method of claim 1, wherein the verification includes verifying the interest the entity has in the at least one corresponding digital asset.

9. The method of claim 1, wherein the verification is performed utilizing a web site capable of making such verification.

10. The method of claim 1, wherein the verification includes associating a risk level with the entity.

11. The method of claim 10, wherein the risk level includes a ratio of first information that is verified with respect to second information that is not verified.

12. The method of claim 10, wherein the interface is provided for the entity based on a risk level threshold.

13. The method of claim 12, wherein the interface is provided for the entity if the entity has a risk level that is less than the risk level threshold.

14. The method of claim 12, wherein the entity is required to call customer service if the entity has a risk level that is greater than the risk level threshold.

15. The method of claim 1, wherein the entity is required to accept a click-through license agreement.

16. The method of claim 1, wherein the entity is required to license at least a portion of a plurality of corresponding digital assets.

17. The method of claim 1, wherein sample selections of digital asset s of the entity are provided to potential purchasers.

18. A computer program embodied on a computer readable medium, comprising:
computer code for receiving, utilizing a network, a request from one of a plurality of entities which each has an interest in at least one corresponding digital asset;
computer code for automatically verifying an eligibility of the entity; and
computer code for conditionally providing an interface for the entity for facilitating transactions involving the at least one digital asset based on the verification.

19. A system, comprising:
a processor for receiving a request from one of a plurality of entities which each has an interest in at least one corresponding digital asset, and conditionally providing an interface for the entity for facilitating transactions involving the at least one digital asset, based on an automatic verification of an eligibility of the entity.
